(19) United States
(12) Patent Application Publication
(10) Pub. No.: US 2007/0034905 A1
(43) Pub. Date: Feb. 15, 2007

(54) Phase-change memory device and its methods of formation

(75) Inventor: Patricia C. Elkins, Boise, ID (US)

Correspondence Address: DICKSTEIN SHAPIRO LLP, 1825 EYE STREET NW, Washington, DC, 20006-5403, US

(73) Assignee: Micron Technology, Inc.

(21) Appl. No.: 11/199,257

(22) Filed: Aug. 9, 2005

(51) Int. Cl. H01L 27/10; H01L 29/74

(52) U.S. Cl. 257/211

(57) ABSTRACT

Phase-change memory device and methods for forming the same. The phase-change memory device comprises a first electrode and at least one phase-change material layer formed over the first electrode. The at least one phase-change material layer further comprising at least one implanted region that has higher thermal characteristics than an adjacent non-implanted region. A second electrode is formed over the at least one phase-change material layer. The phase-change memory device is configured to avoid cross-talk with neighboring phase-change memory devices in a memory array.

### FIELD OF THE INVENTION

The present invention relates to semiconductor memory devices, and in particular, to a phase-change memory device and methods of forming the same.

### BACKGROUND OF THE INVENTION

Electrically writable and erasable phase-change materials are used in semiconductor memory devices. U.S. Pat. Nos. 3,271,591, 3,530,441, and 5,296,716, in the names of Ovshinsky, et al. (“the Ovshinsky patents”), the disclosures of which are incorporated herein by reference. The Ovshinsky patents are believed to indicate generally the state of the art regarding semiconductor memory devices with phase-change materials. A semiconductor memory device that uses a phase-change material may be referred to as a phase-change memory device. Phase-change memory devices, i.e., non-volatile memory or programmable resistance memory, can be formed from materials programmed to exhibit a wide spectrum of high or low stable ohmic states.

Generally, as disclosed in the Ovshinsky patents, such phase-change materials can be electrically switched between a first structural state, where the phase-change material has a generally amorphous local order, i.e., more disordered, and a second structural state, where the phase-change material has a generally crystalline local order, i.e., more ordered. The phase-change material may also be electrically switched between different detectable states of local order across the entire spectrum between the completely amorphous and the completely crystalline states. That is, the switching of such phase-change materials is not required to take place between completely amorphous and completely crystalline states, but rather, the phase-change material can be switched in incremental steps reflecting changes of local order spanning the spectrum from a completely amorphous state to a completely crystalline state. Phase-change materials exhibiting such properties are known as “ovonic” materials.

Phase-change materials such as chalcogenides have been used in phase-change memory devices, i.e., chalcogenide memory devices. Other phase-change materials may also be used. At present, alloys of groups VI of the periodic table, such as Ge, Te, Se, or Sb, i.e., chalcogenides, can advantageously be used in phase-change memory devices. In chalcogenides, the high-resistance state corresponds typically to an amorphous state, i.e., exhibits lower electrical conductivity, while the low-resistance state, i.e., exhibits higher electrical conductivity, corresponds typically to a more ordered crystalline state.

The active regions of the chalcogenide memory devices are believed to change crystalline structure in response to applied voltage pulses of a wide range of magnitudes and pulse durations. These changes in crystalline structure alter the bulk resistance of the chalcogenide material's active region. The wide dynamic range of chalcogenide memory devices, the linearity of their response, and lack of hysteresis provide these memory cells with multiple bit storage capabilities.

The phase-change may be induced reversibly. Therefore, the phase-change memory device may change from the amorphous state to the crystalline state and may revert back to the amorphous state thereafter, or vice versa, in response to temperature changes. The conversion between the amorphous and crystalline states are generally achieved thermally. Phase-change may be obtained by locally increasing the temperature, i.e., above the phase-change material's crystallization point, thereby causing the phase-change material to change its phase and become crystalline. To return the phase-change material back to an amorphous state, it is necessary to raise the temperature above the melting point and then to cool it off rapidly.

From an electrical standpoint, it is possible to reach both critical temperatures, namely the crystallization point and melting point, by causing current to flow through a resistive element that heats the phase-change material by the Joule effect. The phase-change material may be coupled to upper and lower electrodes. The mechanism for this reversible phase-change from the amorphous state to the crystalline state is induced by Joule heating due to the current flow through the material between the upper and lower electrodes.

One problem that arises with phase-change memory devices is that since the change from amorphous to crystalline, and vice versa, may be conducted a plurality of times, the phase-change material surrounding the bits may also be heated to varying degrees dependent on the distance from the active material being phase changed. The thermal spread will induce various amounts of crystallinity in the adjacent inactive material. This would cause a low resistance path between bits compromising the required bit to bit isolation and would limit the minimum possible bit to bit spacing.

In a phase-change memory device, typically the high-resistance represents one binary state and the low-resistance represents a second binary state. For optimal performance, the resistances of these two separate states should be far apart with a tight distribution for each state. Consequently, the area of material that changes phase should be constant and not spread out due to Joule heating from the sides of the bottom electrode to the adjacent bit. When this phenomenon occurs, it is called cross-talk.

In FIG. 1, a memory array with two conventional semiconductor memory devices 50, 60 is illustrated. FIG. 1 also illustrates a substrate 1, trench isolation regions 2, source/drain regions 3, bit line contacts 4, bit lines 6, contacts to metallization line M1, i.e., a storage contact SC and a contact C, dielectric layer 20, sidewall spacers 21, dielectric layer 30, an access transistor 51 for bit electrode 18, and an access transistor 61 for bit electrode 19.

A phase-change material layer 40 is provided over the bit electrode 18 of semiconductor memory device 50 and bit electrode 19 of semiconductor memory device 60. Active regions, i.e., the area of material that changes phase, is provided over bit electrode 18, i.e., active region 5a, and bit electrode 19, i.e., active region 5b. As the phase-change memory devices 50, 60 undergo a plurality of phase-changes from amorphous to crystalline states and vice versa, the active regions 5a, 5b can expand due to Joule heating, forming expanded regions 7. The active regions 5a, 5b eventually expand and connect with each other via the expanded regions 7, thereby causing a short, i.e., creating a low resistance path, between the bit electrode 18 and bit electrode 19, i.e., adjacent bits. These expanded regions 7 reduce the tight distribution for each state of the semiconductor memory devices 50, 60.

Because of the creation of expanded regions 7, the possibility of cross-talk arises between adjacent semiconductor memory devices in a memory array. A need exists, therefore, for a phase-change memory device and a method of forming the same in which cross-talk is reduced, and in which the active regions 5a, 5b of FIG. 1, do not expand to form expanded regions 7 due to Joule heating.

### BRIEF SUMMARY OF THE INVENTION

Embodiments of the invention provide a phase-change memory device and methods for forming the same. The phase-change memory device comprises a first electrode and a phase-change material layer formed over the first electrode. A second electrode is formed over the phase-change material layer. The phase-change material layer further comprises an active region, that undergoes phase-changes, surrounded on each side by a non-active region that is resistant to phase-change. The non-active region comprises dopant ions that prevents it from switching from an amorphous state to a crystalline state and vice versa.

In another embodiment, a phase-change memory device is provided comprising first and second electrodes with at least two phase-change material layers formed between the first and second electrodes. Each of the phase-change material layers further comprises active and inactive regions. In one exemplary embodiment, the phase-change material comprises a chalcogenide material, and the non-active regions comprise an inert species such as argon or nitrogen, which prevents the regions switching between amorphous to crystalline states and vice versa.

### BRIEF DESCRIPTION OF THE DRAWINGS

The foregoing and other advantages and features of the invention will become more apparent from the detailed description of exemplary embodiments provided below with reference to the accompanying drawings in which:

FIG. 1 depicts a phase-change memory device in which cross-talk occurs between two adjacent bits of the device;

FIG. 2 depicts a portion of a phase-change memory array comprising phase-change memory devices according to an embodiment of the invention;

FIG. 3 depicts a portion of a phase-change memory array comprising phase-change memory devices according to another exemplary embodiment of the invention;

FIGS. 4A-4D depict a method of forming a phase-change memory device of FIG. 2 at different stages of processing;

FIGS. 5A-5D depict a method of forming a phase-change memory device of FIG. 3 at different stages of processing; and

FIG. 6 is a block diagram of a system including a phase-change memory device constructed in accordance with an embodiment of the invention.

### DETAILED DESCRIPTION OF THE INVENTION

In the following detailed description, reference is made to various specific embodiments of the invention. These embodiments are described with sufficient detail to enable those skilled in the art to practice the invention. It is to be understood that other embodiments may be employed, and that various structural, logical and electrical changes may be made without departing from the spirit or scope of the invention.

The term “substrate” used in the following description may include any supporting structure including, but not limited to, a semiconductor substrate that has an exposed substrate surface. A semiconductor substrate should be understood to include silicon, silicon-on-insulator (SOI), silicon-on-sapphire (SOS), doped and undoped semiconductors, epitaxial layers of silicon supported by a base semiconductor foundation, and other semiconductor structures. When reference is made to a semiconductor substrate or wafer in the following description, previous process steps may have been utilized to form regions or junctions in or over the base semiconductor or foundation. The substrate need not be semiconductor-based, but may be any support structure suitable for supporting an integrated circuit, including, but not limited to, metals, alloys, glasses, polymers, ceramics, and any other supportive materials as is known in the art.

The term “layer” refers to both a single layer and multiple layers, or strata. The term “layer” can also be understood to refer to a structure that includes multiple layers. Typically, similar fabrication steps and processes, such as patterning and etching, are applied to all layers in the structure. Adjacent layers can be patterned and etched simultaneously.

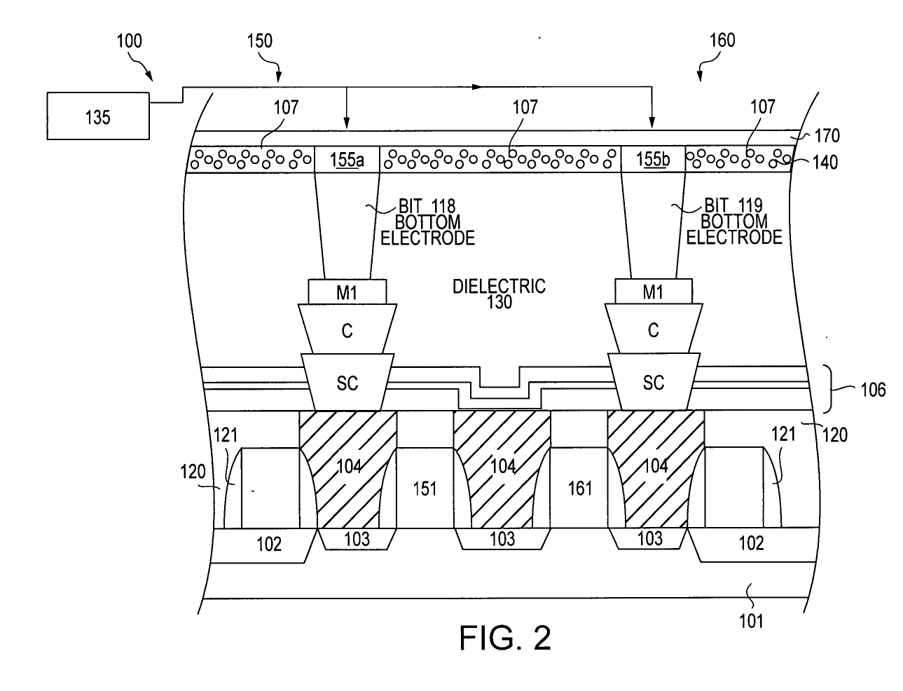

The invention is now explained with reference to the figures, which illustrate exemplary embodiments and throughout which like reference numbers indicate like features. FIG. 2 depicts an exemplary embodiment of a portion of a phase-change memory array 100 with phase-change memory devices 150, 160 constructed in accordance with the invention. The phase-change memory devices 150, 160 are supported by a substrate 101. Formed over substrate 101 are trench isolation regions 102, source/drain regions 103, bit line contacts 104, bit lines 106, contacts SC, C, connected to a metallization line M1, a dielectric layer 120, sidewall spacers 121, and a dielectric layer 130. An access transistor 151 for bit electrode 118 and an access transistor 161 for bit electrode 119 are also provided.

The formation and structure of phase-change memory devices 150, 160, up to the formation of the bit electrode 118 and bit electrode 119 are well-known in the art and will not be discussed for the sake of brevity. For example, the process to form the access transistors 151 and 161, bit electrode 118, and bit electrode 119 can be a “standard” CMOS flow known in the art.

Next, a phase-change material layer 140 is provided over the bit electrode 118 of phase-change memory device 150 and bit electrode 119 of phase-change memory device 160. Active region 155a, i.e., the area of material that changes phase, is provided over bit electrode 118, while active region 155b is provided over bit electrode 119.

Adjacent to active region 155a are implanted regions 107, i.e., non-active regions, formed within phase-change material layer 140. Implanted regions 107 comprise an inert dopant species that prevents the phase-change material layer 140 from transitioning, i.e., switching, from an amorphous state to a crystalline state and vice versa. Similarly, adjacent to active region 155b are the implanted regions 107. Implanted regions 107 are substantially the same thickness as the active regions 155a and 155b.

As the phase-change memory devices 150, 160 undergo a plurality of phase-changes switching from amorphous to crystalline states and vice versa, the active regions 155a, 155b do not expand because of the presence of implanted regions 107. These implanted regions 107 also provide a tight distribution for each state of the phase-change memory devices 150, 160 since the active regions 155a, 155b are confined to a specific area. The overall resistances of the phase-change memory devices 150, 160 are controlled by the active regions 155a, 155b. The active regions 155a, 155b are formed to be substantially the same width as the bit electrode 118 and the bit electrode 119, respectively.

It should be appreciated that the active regions 155a, 155b, however, can be formed wider or smaller in width than the width of the bit electrode 118 and bit electrode 119. It should also be appreciated that intervening layers (not shown) can be present between phase-change layer 140 and the bit electrode 118, the bit electrode 119, and/or the second electrode 170. For instance, the phase-change material of phase-change layer 140 can be formed in a dielectric layer (not shown) that has been etched to have a via exposing the surface of the bottom electrodes 118, 119. In that situation, the phase-change material is deposited within the etched via.

In one embodiment, the implanted regions 107 are uniformly-doped with an inert dopant species such as nitrogen or argon with an implant dose from about 1.0×10¹² cm² to about 1.0×10¹⁵ cm², and the phase-change material comprises Ge₂Sb₂Te₅. It should be appreciated however, that any dopant species, not just an inert species, could be used to form implanted regions 107, so long as the implanted dopant species prevents the phase-change material layer 140, in those implanted regions 107, from transitioning, i.e., switching, from an amorphous state to a crystalline state and vice versa. One non-limiting example of another dopant species that can be used is arsenic.

The implant energy and implant dose vary and depend on the thickness of the phase-change material layer 140. In another embodiment, the implanted regions 107 are formed to have a gradient dopant profile. For instance, the top surface of implanted regions 107, i.e., area farthest away from substrate 101, can be formed to have a higher dopant concentration than the bottom surface and vice versa.

After the phase-change material layer 140 comprising active regions 155a, 155b and non-active regions 107 is formed, a second conductive electrode 170 is formed over the phase-change material layer 140. A pulse generator 135 is then provided to supply pulses and current to the second conductive electrode 170. At this point, the phase-change memory array 100 is essentially complete.

The purpose of providing dopant species to implanted regions 107 is to create regions that have a higher crystallization point and/or melting point than the active regions 155a, 155b which affects the thermal characteristics of the implanted regions 107. The implanted regions 107, thus, can remain in a disordered state (amorphous). In one exemplary embodiment, implanted regions 107 have higher crystallization and melting points than active regions 155a, 155b. For example, if active regions 155a, 155b have a crystallization point of 200° C. and melting points of 325° C., the implanted regions 107 (non-active regions) should have a crystallization and/or melting point greater than 325° C.

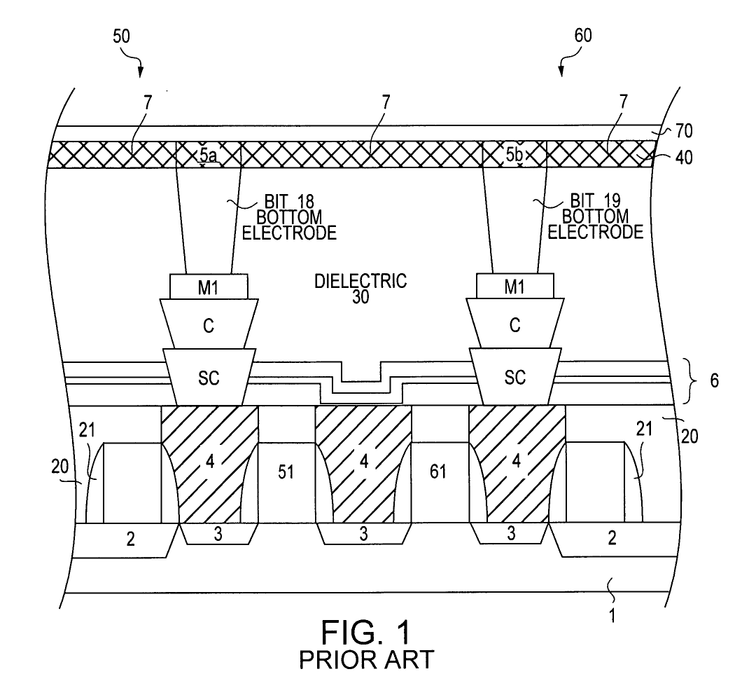

The non-active regions 107, i.e., implanted regions 107, essentially isolates one bit from another bit, i.e., bit electrode 118 of phase-change memory device 150 from bit electrode 119 of phase-change memory device 160. Consequently, the non-active regions 107, surrounding bit electrodes 118, 119, raises the crystallization temperature of the surrounding area in order to maintain its amorphous state, while the adjacent material, i.e., active regions 155a, 155b, crystallizes under the influence of Joule heating due to the applied current pulses from current amplifier 135. This prevents cross-talk between the adjacent phase-change memory devices 150, 160. In addition, the present invention avoids problems associated in the prior art (FIG. 1), in which active regions 5a, 5b expand to formed expanded regions 7 that eventually create a short, i.e., creating a low resistance path, between the bit electrodes 18, 19 of adjacent phase-change memory devices 50 and 60 (FIG. 1).

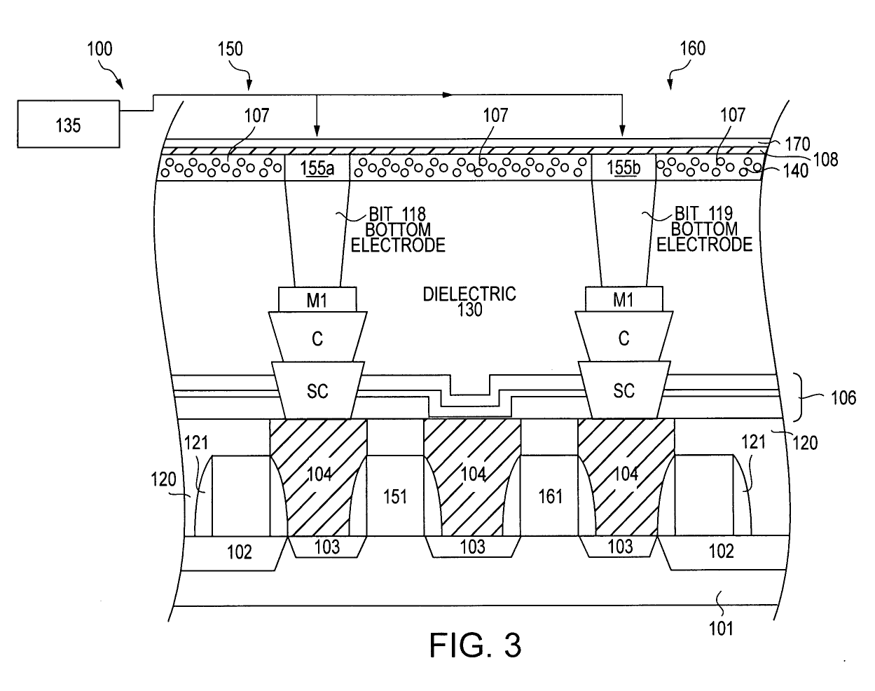

Referring now to FIG. 3, another exemplary embodiment of the invention is provided. In FIG. 3, most of the elements illustrated are the same as described above in connection with FIG. 2. The primary difference is that a second phase-change material layer 141 is formed over the first phase-change material layer 140. The second phase change material layer 141 further comprises active regions, i.e., areas of material that changes phase, provided over active region 155a, i.e., active region 156a, and active region 155b, i.e., active region 156b.

Adjacent to active region 156a, of phase-change memory device 150, are implanted regions 108, i.e., non-active regions, formed within phase-change material layer 141. Similar to implanted regions 107, implanted regions 108 can comprise an inert dopant species and/or any dopant species that prevents the phase-change material layer 141 from transitioning and/or switching from an amorphous state to a crystalline state and vice versa. Similarly, adjacent to active region 156b, of phase-change memory device 160, are the implanted regions 108.

It should be appreciated that the phase-change material layers 140 and 141 can comprise the same phase-change material or different phase-change materials. It should also be appreciated that the implant dopant species used to form implanted regions 107 can be the same and/or different from the implant dopant species used to form implanted regions 108. The implanted regions 108 are formed to have approximately the same thickness as active regions 156a, 156b.

As the phase-change memory devices 150, 160 undergo a plurality of phase-changes switching from amorphous states to crystalline states and vice versa, the active regions 156a, 156b do not expand because of the presence of implanted regions 108. The overall resistances of phase-change memory devices 150, 160 are controlled by the active regions 155a, 155b, 156a, 156b. The active regions 156a, 156b can be formed to be substantially the same width as active region 155a, 155b, respectively.

It should be appreciated that active regions 156a, 156b, however, can be formed wider or smaller in width than the width of active region 155a,155b. It should also be appreciated that intervening layers (not shown) can be present between phase-change layers 140 and 141, and the bit electrode 118, the bit electrode 119, and/or second conductive electrode 170. For instance, the phase-change material, of phase-change layer 141, can be formed in a dielectric layer (not shown) that has been etched to have a via exposing the surface of the bottom electrodes 118, 119. In this situation, the phase-change material is deposited within the etched via.

The implanted regions 108 can be uniformly-doped with an inert implant dopant species such as nitrogen or argon with an implant dose from about 1.0×10¹² cm² to about 1.0×10¹⁵ cm², and the phase-change material can comprise Ge₂Sb₂Te₅. It should be appreciated however, that any implant dopant could be used to form implanted regions 108, so long as the implanted dopant prevents the phase-change material layer 141, in those implanted regions 108, from transitioning and/or switching from an amorphous state to a crystalline state and vice versa. One non-limiting example of another implant dopant that can be used is arsenic.

The implant energy and implant dose vary and depend on the thickness of the phase-change material layer 141. The implanted regions 108 can also be formed to have a gradient dopant profile. For instance, the top surface of implanted regions 108, i.e., area farthest away from substrate 101, can be formed to have a higher dopant concentration than the bottom surface and vice versa.

After the phase-change material layer 141 comprising active regions 156a, 156b and non-active regions 108 is formed, a second conductive electrode 170 is formed over the phase-change material layer 141. A pulse generator 135 is then provided to supply pulses and current to the second electrode 170. At this point, the phase-change memory array 100 is essentially complete according to the second embodiment of the invention.

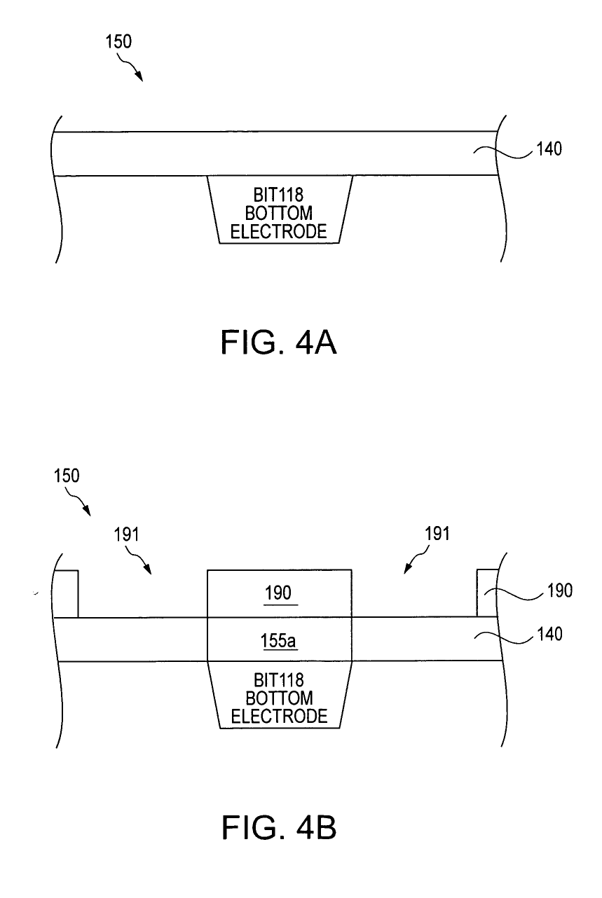

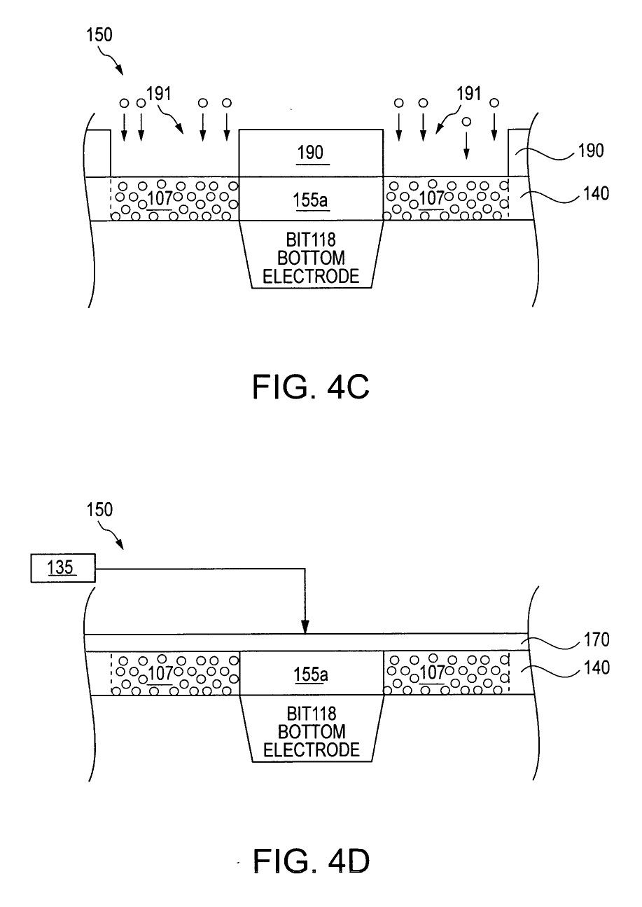

FIGS. 4A-4D are partial cross-sectional views of FIG. 2, taken along lines 2-2′, depicting the formation of phase-change memory device 150 according to an exemplary embodiment of the invention. No particular order is required for any of the actions described herein (FIGS. 4A-4D), except for those logically requiring the results of prior actions. Accordingly, while the actions below are described as being performed in a specific order, the order is exemplary only and can be altered, if desired. Moreover, although the formation of a single phase-change memory device 150 is described, it should be appreciated that these steps can be used to form a plurality of phase-change memory devices in a phase-change memory array. All of which can be formed concurrently.

For purposes of brevity, the phase-change memory device 150 is illustrated as being formed on the bit electrode 118. However, as FIGS. 2 and 3 illustrate, there are a plurality of elements formed below and in electrical contact with the bit electrode 118. The formation of the phase-change memory device 150, up to the formation of the bit electrode 118 is well-known in the art and is not described herein.

Referring now to FIG. 4A, a phase-change material layer 140 is provided over the bit electrode 118 of phase-change memory device 150. The phase-change material can be deposited with a thickness of from about 50 Å to about 2000 Å, and more specifically, to about 500 Å thick. In one exemplary embodiment, the phase-change material layer 140 comprises a chalcogenide material, such as alloys of groups VI of the periodic table, i.e., Ge, Te, Sb, or Se. Other phase-change materials may also be used. In a non-limiting example, phase-change material layer 140 can comprise Ge₂Sb₂Te₅.

It should be appreciated that intervening layers can be formed between phase-change layer 140 and the bit electrode 118 so long as the phase-change layer 140 remains in electrical contact with the bit electrode 118. For instance, a dielectric layer (not shown) can be formed over the bit electrode 118. The dielectric layer would then be etched to form an opening exposing at least a portion of the bit electrode 118. In this situation, the phase-change layer is deposited within the etched opening.

Referring now to FIG. 4B, a photoresist or masking layer 190 is formed over the phase-change material layer 140. The photoresist layer 190 is exposed and patterned to form a plurality of openings 191 within the photoresist layer 190. The photoresist layer 190 can be patterned to allow the width of active region 155a to be substantially the same as the width of the bit electrode 118. In other embodiments, photoresist layer 190 can be patterned to allow the width of active region 155a to be smaller or wider than the width of the bit electrode 118.

Again, intervening layers can be formed between the phase-change material layer 140 and the photoresist layer 190, so long as the phase-change material layer 140 remains in electrical contact with the bit electrode 118 and a subsequently deposited top electrode layer. The purpose of the photoresist or masking layer 190 is to pattern the areas on the phase-change material layer 140 that will receive the dopant implant species. These areas eventually form the non-active regions, i.e., implanted regions that do not undergo phase-change.

Referring now to FIG. 4C, an implant step is performed using photoresist layer 190 as a mask. The implant dopant is implanted through openings 191 in the photoresist layer 190. The implanted dopant species form the implanted regions 107. The implanted regions 107 can comprise an inert dopant species that prevents the phase-change material layer 140 from switching from an amorphous state to a crystalline state and vice versa. FIG. 4C illustrates that the implanted regions 107 are formed on either side of the active region 155a. The implanted regions 107 are also formed to have approximately the same thickness as active region 155a. After the implant step is completed, the photoresist 190 is removed by techniques well-known in the art.

The implant dopant species used can be nitrogen or argon. The implant dose can be from about 1.0×10¹² cm² to about 1.0×10¹⁵ cm² with an implant energy of from about 30 to about 50 Kev. It should be appreciated that any implant dopant could be used to form implanted regions 107, so long as the implanted dopant prevents the phase-change material layer 140, in those implanted regions 107, from transitioning from an amorphous state to a crystalline state and vice versa. One non-limiting example of another implant dopant species that can be used is arsenic.

The implant energy and implant dose will vary and depend on the thickness of the phase-change material layer 140. In one embodiment, the implanted regions 107 have a uniform dopant profile. In another embodiment, the implanted regions 107 can be formed to have a gradient dopant profile. For instance, the top surface of implanted regions 107, i.e., area farthest away from the bit electrode 118, can be formed to have a higher dopant concentration than the bottom surface, which is closest to the bit electrode 118 and vice versa.

The active region 155a is provided over the bit electrode 118, which is isolated from adjacent bit electrodes by implanted regions 107. The implanted regions 107, i.e., non-active regions, prevent the phase-change material layer 140 from switching from an amorphous state to a crystalline state and vice versa, in those implanted regions 107. In other words, only the active region 155a undergoes phase-change. The active region 155a does not expand because of the presence of implanted regions 107. Consequently, the overall resistance of phase-change memory device 150 is substantially controlled by the active region's 155a ability to phase-change.

Referring now to FIG. 4D, after the phase-change material layer 140 comprising active region 155a and non-active regions 107 is formed, a second conductive electrode 170 is formed over the phase-change material layer 140. The bit electrode 118 and second conductive electrode 170 can be formed of any conductive materials and thicknesses as is known in the art. A pulse generator 135 is then provided to supply pulses and current to the second electrode 170. At this point, the phase-change memory device 150 is essentially complete.

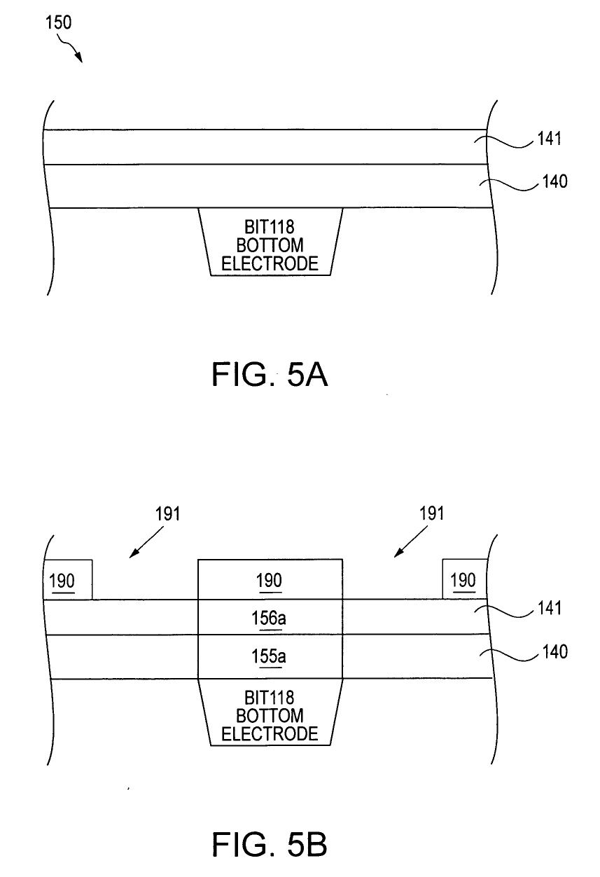

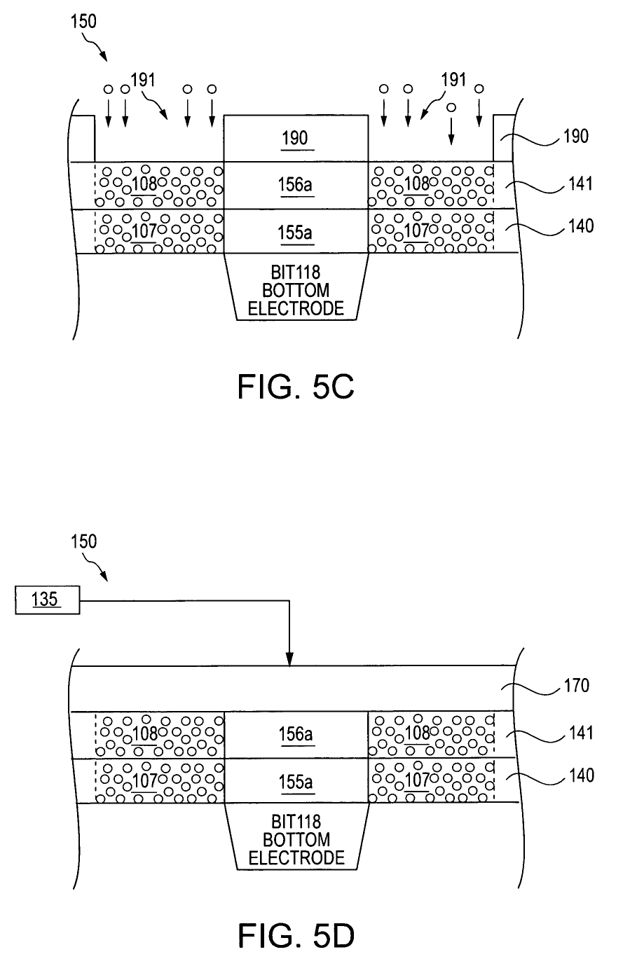

Referring now to FIGS. 5A-5D, another exemplary method is illustrated. FIGS. 5A-5D are partial cross-sectional views of FIG. 3, taken along lines 2-2′, depicting the formation of the phase-change memory device 150 according to the exemplary embodiment of the invention depicted in FIG. 3. FIG. 5A is also step subsequent to that illustrated in FIG. 4A.

No particular order is required for any of the actions described herein (FIGS. 5A-5D), except for those logically requiring the results of prior actions. Accordingly, while the actions below are described as being performed in a specific order, the order is exemplary only and can be altered, if desired. Moreover, although the formation of a single phase-change memory device 150 is described, it should be appreciated that these steps can be used to form a plurality of phase-change memory devices in an array of phase-change memory devices. All of which can be formed concurrently.

Referring to FIG. 5A, a second phase-change material layer 141 is formed over the first phase-change material layer 140. The second phase-change material layer 141 can comprise the same phase-change material as the first phase-change material layer 140, or can comprise a different phase-change material. The second phase-change material layer 141 can be formed in contact with phase-change material layer 140 or intervening layers can be present.

Intervening layers can be formed between the phase-change layers 140, 141, so long as the phase-change material layers 140, 141 remain in electrical contact with the bit electrode 118 and a subsequently deposited top electrode. The phase-change material layers 140, 141 can be formed to have the same or different thickness. It should also be appreciated that a plurality of phase-change material layers, or intervening layers can be formed over the second phase-change material layer 141, if desired so long as all of the phase-change material layers remain in electrical contact with the bit electrode 118 and a subsequently deposited top electrode.

Referring now to FIG. 5B, a photoresist or masking layer 190 is formed over the first and second phase-change material layers 140, 141. The photoresist layer 190 is exposed and patterned to form a plurality of openings 191 within the photoresist layer 190. The photoresist layer 190 can be patterned to allow the widths of the active regions 155a, 156a to be substantially the same as the width of the bit electrode 118.

In other embodiments, a first photoresist layer can be formed prior to the deposition of the second phase-change material layer 141, and then patterned to form a first active region 155a having a first width. In this situation, the second phase-change material layer 141 is formed over the first phase-change material layer 140. A second photoresist layer is formed and then patterned to form a second active region 156a having a second width. Consequently, the widths of active regions 155a, 156a can be changed with a simple modification.

Still referring to FIG. 5B, the plurality of openings 191 is formed to correspond to areas within phase-change layers 141, 140 that are predetermined to be non-active areas. These non-active areas would form the non-active regions 107, 108.

Referring now to FIG. 5C, an ion dopant implant is performed using photoresist layer 190 as a mask. The implant dopant is implanted through openings 191 in the photoresist layer 190. The implanted dopant form implanted regions 107, 108. The implanted regions 107, 108 can comprise an inert dopant species that prevents the phase-change material layers 140, 141 from switching from an amorphous state to a crystalline state and vice versa.

FIG. 5C illustrates that the implanted regions 107, 108 are formed on a side of active regions 155a, 156a. The implanted regions 107, 108 are also formed to have approximately the same thickness as active regions 155a, 156a, respectively. After the implant step is completed, the photoresist 190 is removed by techniques well-known in the art.

The implant dopant species used can be nitrogen or argon. The implant dose can be from about 1.0×10¹² cm² to about 1.0×10¹⁵ cm² with an implant energy of from about 30 to about 50 Kev. It should be appreciated that any implant dopant could be used to form implanted regions 107, 108, so long as the implanted dopant prevents the phase-change material layers 140, 141, in those implanted regions 107, 108, from switching from an amorphous state to a crystalline state and vice versa. One non-limiting example of another implant dopant that can be used is arsenic.

The implant energy and implant dose will vary and depend on the thicknesses of the phase-change material layers 140, 141. It should also be appreciated that two separate implants can be done. A first implant with a first implant energy and dose to form implanted region 107, and then a second implant with a second implant energy and dose to form implanted region 108. In one embodiment, the implanted regions 107, 108 have a uniform dopant profile and the same implant dopant concentrations.

In another embodiment, the implanted regions 107, 108 can be formed to have a gradient dopant profile. For instance, the top surface of implanted regions 108, i.e., area farthest away from the bit electrode 118, can be formed to have a higher dopant concentration than the bottom surface of implant regions 107, which is closest to the bit electrode 118, and vice versa.

The active regions 155a, 156a are provided over the bit electrode 118, which is isolated from adjacent bit electrodes by implanted regions 107, 108. The implanted regions 107, 108, i.e., non-active regions, prevent the phase-change material layers 140, 141 from transitioning from an amorphous state to a crystalline state and vice versa in those implanted regions 107, 108.

In other words, only the active regions 155a, 156a undergoes phase-change. The active regions 155a, 156a do not expand because of the presence of implanted regions 107, 108. Consequently, the overall resistance of phase-change memory device 150 is substantially controlled by the active regions' 155a, 156a abilities to phase-change.

Referring now to FIG. 5D, after the phase-change material layers 140, 141, comprising active regions 155a, 156a, and non-active regions 107, 108, are formed, a second conductive electrode 170 is formed over the phase-change material layer 141. The bit electrode 118 and second conductive electrode 170 can be formed of any conductive materials and thicknesses as-is known in the art. A pulse generator 135 is then provided to supply pulses and current to the second electrode 170. At this point, the phase-change memory device 150 is essentially complete constructed in accordance with another exemplary embodiment of the invention.

Additional processing steps can be performed after the methods illustrated in FIGS. 4D and 5D are completed. For example the formation of connections to other circuitry of the integrated circuit, e.g., logic circuitry, sense amplifiers, etc., of which the phase-change memory device 150 is a part, as-is known in the art.

The implanted regions 107, 108 of FIGS. 2 and 3, respectively, prevent the phase-change material in the phase-change material layers 140, 141, respectively, from crystallizing. In essence, the implanted regions 107, 108 have different thermal characteristics from the active regions 155a, 156a, 155b, 156b. Consequently, the implanted regions 107, 108 remain in an amorphous state upon the application of voltage pulses from pulse generator 135, while the active regions 155a, 156a, 155b, 156b are crystallizing under the influence of Joule heating due to the voltage pulses.

The crystallization of the active regions 155a, 156a, 155b, 156b is confined and stops at the boundary of the implanted regions 107, 108. This in turn, confines the volume of the phase-change. The implant dopant used alters the structure and stoichiometry between adjacent bits resulting in between bit regions, i.e., implanted regions 107, 108, that do not crystallize at the same rate as the bits themselves. Since the crystallization of active regions 155a, 156a, 155b, 156b is confined to the respective active regions, the crystallization does not reach an adjacent bit effectively shorting, i.e., cross-talk, the bits together as can occur in prior art phase-change memory devices 50, 60 (FIG. 1).

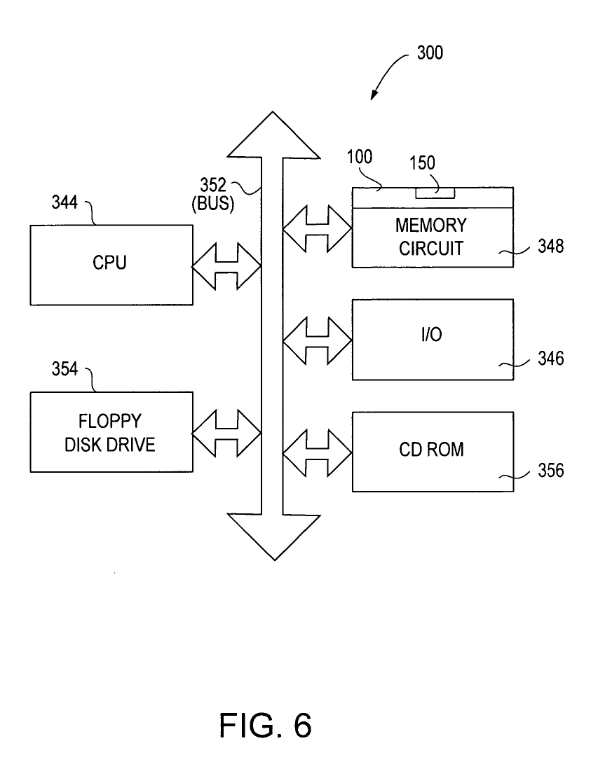

FIG. 6 illustrates a processor system 300 that includes a memory circuit 348, e.g., a memory device, which employs a phase-change memory array 100 having at least one phase-change memory device 150 constructed in accordance with the invention. The processor system 300, which can be, for example, a computer system, generally comprises a central processing unit (CPU) 344, such as a microprocessor, a digital signal processor, or other programmable digital logic devices, which communicates with an input/output (I/O) device 346 over a bus 352. The memory circuit 348 communicates with the CPU 344 over bus 352 typically through a memory controller.

In the case of a computer system, the processor system 300 may include peripheral devices such as a floppy disk drive 354 and a compact disc (CD) ROM drive 356, which also communicate with CPU 344 over the bus 352. Memory circuit 348 is preferably constructed as an integrated circuit, which includes a memory array 100 having at least one phase-change memory device 150 according to the invention. If desired, the memory circuit 348 may be combined with the processor, for example CPU 344, in a single integrated circuit.

The above description and drawings are only to be considered illustrative of exemplary embodiments, which achieve the features and advantages of the present invention. Modification and substitutions to specific process conditions and structures can be made without departing from the spirit and scope of the present invention. Accordingly, the invention is not to be considered as being limited by the foregoing description and drawings, but is only limited by the scope of the appended claims.

What is claimed as new and desired to be protected by Letters Patent of the United States is:

1. A phase-change memory device comprising:
a first electrode;
at least one phase-change material layer formed over the first electrode, said phase-change material layer comprising an active region and at least two non-active regions formed adjacent to said active region; and
a second electrode formed over the at least one phase-change material layer.

2. The phase-change memory device of claim 1, wherein said non-active regions have a higher thermal characteristic than said active region.

3. The phase-change memory device of claim 1, wherein the phase-change material layer comprises a chalcogenide material.

4. The phase-change memory device of claim 1, wherein said non-active active regions have substantially the same thickness.

5. The phase-change memory device of claim 1, wherein said active region has substantially the same width as the first electrode.

6. The phase-change memory device of claim 1, further comprising a second phase-change material layer formed over the at least one phase-change material layer, wherein said second phase-change material layer comprising at least two non-active regions and a second active region.

7. The phase-change memory device of claim 6, wherein said second active region is substantially the same size as the active region within the at least one phase-change material layer.

8. A phase-change memory device comprising:
a first electrode;
at least one phase-change material layer formed over the first electrode, said phase-change material layer comprising implanted regions adjacent to non-implanted regions; and
a second electrode formed over the at least one phase-change material layer.

9. The phase-change memory device of claim 8, wherein said implanted regions have a higher thermal characteristic than said non-implanted regions.

10. The phase-change memory device of claim 8, wherein said implanted and non-implanted regions have substantially the same thickness.

11. The phase-change memory device of claim 8, wherein said non-implanted regions are substantially the same width as the first electrode.

12. The phase-change memory device of claim 8, further comprising a second phase-change material layer formed over the at least one phase-change material layer, wherein said second phase-change material layer further comprising at least two implanted regions and a second non-implanted region.

13. The phase-change memory device of claim 12, wherein said second non-implanted region is substantially the same size as the non-implanted region within the at least one phase-change material layer.

14. The phase-change memory device of claim 8, wherein said implanted regions comprise inert implant dopant species.

15. The phase-change memory device of claim 14, wherein said inert implant dopant species are selected from the group consisting of argon, nitrogen, and arsenic.

16. A phase-change memory device comprising:
a first electrode;
at least one chalcogenide layer formed over the first electrode, said chalcogenide layer having first and second regions, said first region having a higher crystallization point than the second region, wherein said first and second regions are adjacent to each other; and
a second electrode formed over the at least one chalcogenide layer.

17. A phase-change memory array comprising:
a plurality of phase-change memory devices, at least one phase-change memory device comprising:
a first electrode;
at least one phase-change material layer formed over the first electrode, said phase-change material layer further comprising implanted regions adjacent to non-implanted regions; and
a second electrode formed over the at least one phase-change material layer.

18. The phase-change memory array of claim 17, wherein said implanted regions have a higher thermal characteristic than said non-implanted regions.

19. The phase-change memory array of claim 17, wherein said implanted and non-implanted regions have substantially the same thickness.

20. The phase-change memory array of claim 17, wherein said non-implanted regions have substantially the same width as the first electrode.

21. The phase-change memory array of claim 17, further comprising a second phase-change material layer formed over the at least one phase-change material layer, wherein said second phase-change material layer further comprising at least two implanted regions and a second non-implanted region.

22. The phase-change memory array of claim 17, wherein said second non-implanted region is substantially the same size as the non-implanted region within the at least one phase-change material layer.

23. The phase-change memory array of claim 17, wherein said implanted regions comprise an inert implant dopant species.

24. The phase-change memory array of claim 23, wherein said inert implant dopant species are selected from the group consisting of argon, nitrogen, and arsenic.

25. A processor system comprising:
a processor; and
a memory device comprising a phase-change memory device, the phase-change memory device comprising:
a first electrode;
at least one phase-change material layer formed over the first electrode, said phase-change material layer further comprising an active and at least two non-active regions, said non-active regions formed adjacent to said active region; and
a second electrode formed over the at least one phase-change material layer.

26. A method of forming a phase-change memory device, the method comprising:
forming a first conductive layer;
forming at least one phase-change material layer over the first conductive layer;
forming an active region in at least a portion of the at least one phase-change material layer and at least two non-active regions adjacent to said active region;
implanting dopant species into said at least two non-active regions; and
forming a second conductive layer over the at least one phase-change material layer, at least two non-active and active regions.

27. The method of claim 26, wherein said step of forming at least two non-active regions further comprises forming a photoresist over said at least one phase-change material layer.

28. The method of claim 27, wherein said photoresist is patterned to have a plurality of openings corresponding to the location of said at least two non-active regions, and wherein said dopant species are implanted through said openings.

29. The method of claim 26, further comprising the step of forming a second phase-change material layer over the at least one phase-change material layer, wherein said second phase-change material layer is formed to have at least two non-active regions and a second active region.

30. The method of claim 26, wherein said step of implanting dopant species further comprises performing an implant dose of about 1.0×10¹² cm² to about 1.0×10¹⁵ cm².

31. The method of claim 30, wherein an implant energy of the dose is from about 30 to about 50 Kev.

32. The method of claim 26, wherein said non-active regions are formed to have a higher crystallization point than said active region.

33. A method of forming a phase-change memory device, the method comprising:
forming a first electrode;
forming at least one phase-change material layer over the first electrode;
forming a non-implanted region and an implanted region laterally adjacent to each other in a portion of the at least one phase-change material layer, said implanted region comprising an inert dopant species; and
forming a second electrode over the at least one phase-change material layer.

34. The method of claim 33, wherein said step of forming the implanted region further comprises the step of forming a photoresist over said at least one phase-change material layer.

35. The method of claim 34, wherein said photoresist is patterned to have a plurality of openings corresponding to the location of said implanted region, wherein said implanted region is formed by the step of implanting the inert dopant species through said openings.

36. The method of claim 33, wherein said implanted region is formed with an implant dose of about 1.0×10¹² cm² to about 1.0×10¹⁵ cm².

37. The method of claim 33, wherein said implanted region is formed to have a higher crystallization point than said non-implanted region.

38. A method of forming a chalcogenide memory device, said method comprising:
forming a first electrode;
forming at least one chalcogenide layer over the first electrode;
forming a patterned photoresist over said at least one chalcogenide layer, wherein said patterned photoresist has a plurality of openings;
implanting dopant species into the plurality of openings in said patterned photoresist, said step of implanting forming an implanted region within said at least one chalcogenide layer, wherein said implanted region has a higher crystallization point than non-implanted regions;
removing said patterned photoresist; and
forming a second electrode over the at least one chalcogenide layer.
